(19) United States
(12) Patent Application Publication
(10) Pub. No.: US 2025/0179687 A1
(43) Pub. Date: Jun. 5, 2025

(54) METHOD FOR MANUFACTURING AN INGOT AND SINGLE CRYSTAL GROWING FURNACE

(71) Applicants: Qinghai Jinko Solar Co., Ltd., Xining City, Qinghai Province (CN); JINKO SOLAR CO., LTD., SHANGRAO, JIANGXI (CN)

(72) Inventors: Zhancang CHEN, Xining (CN); Ziyang OU, Xining (CN); Jianxing WEI, Xining (CN); Yuzhi ZHAO, Xining (CN)

(21) Appl. No.: 18/395,658

(22) Filed: Dec. 25, 2023

(30) Foreign Application Priority Data
Nov. 30, 2023 (CN) 202311628287.8

(51) Int. Cl. C30B 29/06; C30B 15/14; C30B 15/20

(52) U.S. Cl. CPC C30B 29/06; C30B 15/14; C30B 15/20

(57) ABSTRACT

Provided are a method for manufacturing a single-crystal silicon ingot and a single crystal growing furnace. The furnace includes a furnace body, a heat insulation cylinder, a heater, and a crucible. The heat insulation cylinder is arranged in the furnace body. The heater is arranged in the heat insulation cylinder and located on a periphery of the crucible. The heat insulation cylinder includes an upper heat insulation cylinder, a middle heat insulation cylinder, a lower heat insulation cylinder, and a support ring. The support ring is located between the upper heat insulation cylinder and the middle heat insulation cylinder. Along a height direction of the single crystal growing furnace, a distance between the top of the heater and the bottom of the support ring is an oxygen passing gap. The heater is movable relative to the support ring to adjust the oxygen passing gap.

### CROSS-REFERENCE TO RELATED DISCLOSURE

The present disclosure claims priority to Chinese Patent Application No. 202311628287.8, filed on Nov. 30, 2023, the content of which is incorporated herein by reference in its entirety.

### TECHNICAL FIELD

The present disclosure relates to the technical field of ingot manufacturing, and in particular, to a method for manufacturing an ingot and a single crystal growing furnace.

### BACKGROUND

A single crystal growing furnace is an essential apparatus for crystal growth, and generally includes a furnace body and a heater fixed in the furnace body. Process requirements of various procedures during manufacturing are strictly controlled, so how to grow a higher-quality single crystal is profitable in the industry. Higher quality in the single crystal pulling stage often means lower oxygen content in a single crystalline silicon wafer, but a decrease in the oxygen content may also lead to a decrease in a survival rate of the single crystal. How to grow a higher-quality single crystal has also become important in the industry.

### SUMMARY

The present disclosure provides a method for manufacturing an ingot and a single crystal growing furnace.

According to one aspect of the present disclosure, a method for manufacturing an ingot is provided. The method is used in a single crystal growing furnace to manufacture a single-crystal silicon ingot. The single crystal growing furnace includes a furnace body, a heat insulation cylinder, a heater, and a crucible. The heat insulation cylinder is arranged in the furnace body, the heater is arranged in the heat insulation cylinder, and the heater is located on a periphery of the crucible. The heat insulation cylinder includes an upper heat insulation cylinder, a middle heat insulation cylinder, a lower heat insulation cylinder, and a support ring. The support ring is located between the upper heat insulation cylinder and the middle heat insulation cylinder. Along a height direction of the single crystal growing furnace, a distance between a top of the heater and a bottom of the support ring is an oxygen passing gap, and the heater is movable relative to the support ring to adjust the oxygen passing gap.

The method includes: silicon melting, seeding, shoulder putting, shoulder turning, constant-diameter growth, tailing, and cooling. In the stage of seeding, the oxygen passing gap is a first distance, and in the stage of constant-diameter growth, the oxygen passing gap is a second distance, where the first distance is greater than the second distance.

According to another aspect of the present disclosure, a single crystal growing furnace is provided. The single crystal growing furnace includes: a furnace body, a heat insulation cylinder arranged in the furnace body, a crucible arranged in the heat insulation cylinder, a heater arranged in the heat insulation cylinder and located on a periphery of the crucible, and a driving member connected to the heater.

The heat insulation cylinder includes an upper heat insulation cylinder, a middle heat insulation cylinder, a lower heat insulation cylinder, and a support ring, and the support ring is located between the upper heat insulation cylinder and the middle heat insulation cylinder. Along a height direction of the single crystal growing furnace, a distance between a top of the heater and a bottom of the support ring is an oxygen passing gap. The driving member is configured to drive the heater to move relative to the heat insulation cylinder to adjust the oxygen passing gap.

It should be understood that the general description above and the detailed description in the following are merely exemplary, and do not limit the present disclosure.

### BRIEF DESCRIPTION OF DRAWINGS

FIG. 1 is a schematic sectional view of a single crystal growing furnace according to the present disclosure;

FIG. 2 is a schematic enlarged view of Part A in FIG. 1;

FIG. 3 is a schematic structural diagram of a heater according to the present disclosure; and

FIG. 4 is a schematic structural diagram of a driving member according to the present disclosure.

The accompanying drawings herein, which are incorporated in and constitute a part of this specification, illustrate embodiments consistent with the present disclosure and, together with the specification, serve to explain principles of the present disclosure.

### DESCRIPTION OF EMBODIMENTS

In order to better understand the technical solution of the present disclosure, some embodiments of the present disclosure will be described in detail below with reference to the accompanying drawings.

It should be clear that the described embodiments are only some of rather than all of the embodiments of the present disclosure. Based on the embodiments in the present disclosure, all other embodiments obtained by those of ordinary skill in the art without creative efforts fall within the protection scope of the present disclosure.

The terms used in the embodiments of the present disclosure are for the purpose of describing specific embodiments only and are not intended to limit the present disclosure. The singular forms of “a/an”, “said”, and “the” used in the embodiments of the present disclosure and the appended claims may also include plural forms, unless otherwise clearly specified by the context.

It should be understood that the term “and/or” used herein merely describes an association relationship between associated objects and represents that three relationships may exist. For example, A and/or B may represent the following three cases: only A exists, both A and B exist, and only B exists. In addition, the character “/” generally indicates an “or” relationship between the associated objects.

It is to be noted that the direction words “up”, “down”, “left”, and “right” described in the embodiments of the present disclosure are all based on the directions shown in the drawings, and should not be understood as limiting the embodiments of the present disclosure. In addition, in the context, it is to be further understood that, when it is mentioned that an element is formed “up” or “down” on another element, the element not only be directly formed “up” or “down” on another element, but also indirectly formed “up” or “down” on another element through an intermediate element.

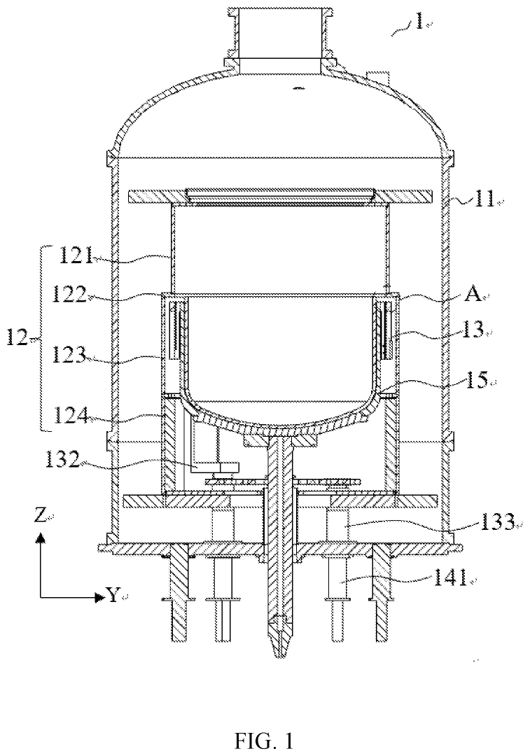

This embodiment provides an ingot manufacturing method, used in a single crystal growing furnace to manufacture a single-crystal silicon ingot. As shown in FIG. 1, the single crystal growing furnace 1 includes a furnace body 11, a heat insulation cylinder 12, a heater 13, and a crucible 15. The heat insulation cylinder 12 is arranged in the furnace body 11. The heater 13 is arranged in the heat insulation cylinder 12 and is located on a periphery of the crucible 15. An upper surface of the heater 13 and an upper surface of the crucible 15 are at a same height. Crystal pulling is based on the following basic principle. A raw material is placed in the crucible 15, a rod capable of rotating and lifting a seed crystal is provided above the crucible 15, and the seed crystal is fixed to a lower end of the rod. After the raw material is melted by the heater 13, the seed crystal is inserted into the melt and an appropriate temperature is provided to reach a supersaturation temperature. A required single-crystal silicon ingot can be obtained by rotating and pulling.

As shown in FIG. 1, the heat insulation cylinder 12 includes an upper heat insulation cylinder 121, a middle heat insulation cylinder 123, a lower heat insulation cylinder 124, and a support ring 122. The upper heat insulation cylinder 121, the middle heat insulation cylinder 123, and the lower heat insulation cylinder 124 are sequentially arranged along a height direction Z of the single crystal growing furnace 1. Diameters of the lower heat insulation cylinder 124 and the middle heat insulation cylinder 123 are the same. The middle heat insulation cylinder 123 may be directly connected to the lower heat insulation cylinder 124. A diameter of the upper heat insulation cylinder 121 is less than that of the middle heat insulation cylinder 123. The support ring 122 is arranged between the upper heat insulation cylinder 121 and the middle heat insulation cylinder 123 for transitional support, to realize a connection between the upper heat insulation cylinder 121 and the middle heat insulation cylinder 123.

The support ring 122 has an annular structure. The support ring 122 has a certain width. An outer edge part of the support ring 122 fits the middle heat insulation cylinder 123, and an inner edge part of the support ring 122 fits the upper heat insulation cylinder 121, to realize the connection between the upper heat insulation cylinder 121 and the middle heat insulation cylinder 123 with different diameters.

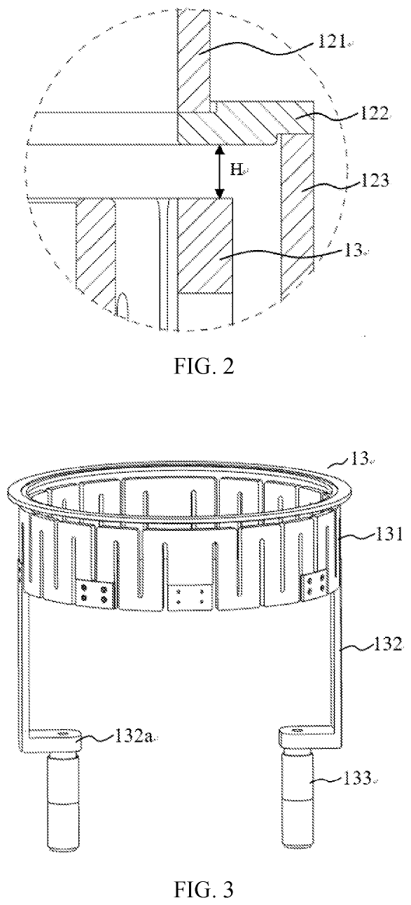

As shown in FIG. 2, along the height direction Z of the single crystal growing furnace 1, the heater 13 is located below the support ring 122, and a distance between the top of the heater 13 and the bottom of the support ring 122 is an oxygen passing gap H. For example, a vertical distance between an upper edge of the heater 13 on the periphery of the crucible 15 and a lower edge of the support ring 122 is the oxygen passing gap H. A size of the oxygen passing gap H is used to control oxygen concentration during single crystal growth. If the oxygen passing gap H is larger, a flow rate of oxygen is lower, and less oxygen is discharged outwards, which means that there is more oxygen content during the single crystal growth. If the oxygen passing gap H is smaller, the flow rate of oxygen is higher, and more oxygen is discharged outwards, which means that there is less oxygen content during the single crystal growth.

For example, a method for manufacturing a single-crystal silicon ingot includes: silicon melting, seeding, shoulder putting, shoulder turning, constant-diameter growth, tailing, and cooling. Constant-diameter growth may also be referred to as body growth or cylindrical growth. Tailing may also be referred to as end cone growth. In the stage of silicon melting, after raw material for manufacturing crystalline silicon is placed in the crucible 15, the heater 13 is turned on to melt the raw material. An example of the raw material is polysilicon. In the stage of seeding, a seed crystal in introduced, for example dipped, to the raw material melt, and the seed crystal has a reduced diameter and grows to a sufficient length. The seed crystal is grown at a surface by an angle of dislocation growth. In the stage of shoulder putting, through coordinated control over a temperature and a pulling speed, the diameter of the crystal gradually increases to a required diameter. In the stage of shoulder turning, by increasing the temperature and the pulling speed, the diameter of the crystal no longer grows and the crystal begins to grow along a length direction with a constant diameter. In the stage of constant-diameter growth, the crystal maintains constant-diameter growth through control over the temperature and the pulling speed. In the stage of tailing, when the crystal grows to a target length, the diameter of the crystal is rapidly reduced by increasing the temperature and the pulling speed, and finally the tail is separated from a liquid surface. After furnace is shutdown, the single crystal growing furnace is disassembled for cleaning. After cleaning and drying, the single crystal growing furnace is assembled for later use. The stages of seeding and shoulder putting take about 150 min, the stage of shoulder turning takes about 10 min, and the stage of constant-diameter growth takes about 40 h to 60 h.

There are two factors that are very important in forming the single-crystal silicon ingot. One factor is a survival rate of the seeding, and the other factor is oxygen content during constant-diameter growth. During the seeding, the higher the oxygen content, the better, in order to improve the survival rate and unit yield of the seeding. During the constant-diameter growth, the lower the oxygen content, the better, in order to improve quality of the single-crystal silicon ingot. In one method, the oxygen passing gap His a fixed value. Generally, during the assembling of the furnace, the heat insulation cylinder as a whole is raised or lowered by adding a felt to or removing a felt below the heat insulation cylinder 12, and a height of the support ring 122 may change as the heat insulation cylinder 12 is raised or lowered, so as to adjust the oxygen passing gap H. The two situations cannot be taken into account at the same time.

To this end, in this embodiment, during the manufacturing of the single-crystal silicon ingot, the heater 13 can move relative to the support ring 122 to adjust the oxygen passing gap H. For example, during the manufacturing of the single-crystal silicon ingot, a position of the heater 13 relative to the support ring 122 is moved, to adjust the oxygen passing gap H in the stage of seeding to a first distance H₁ and to adjust the oxygen passing gap H in the stage of constant-diameter growth to a second distance H₂. The first distance H₁ is greater than the second distance H₂.

In this embodiment, during the manufacturing of the single-crystal silicon ingot, the position of the heater 13 relative to the support ring 122 is adjusted, so that the oxygen passing gap H in the stage of seeding is larger than the oxygen passing gap H in the stage of constant-diameter growth. As a result, a flow rate of oxygen discharged along the oxygen passing gap H is lower in the stage of seeding, and the oxygen content in the single crystal growing furnace 1 is higher in the stage of seeding, thereby increasing the seeding survival rate and improving productivity. The oxygen passing gap H is reduced in the stage of constant-diameter growth, so that the flow rate of oxygen discharged along the oxygen passing gap H is higher, and there is lower oxygen content in the single crystal growing furnace 1 in the stage of constant-diameter growth, thereby improving quality of the single-crystal silicon ingot. In this embodiment, the heater 13 is controlled to move relative to the support ring 122 during the manufacturing of the single-crystal silicon ingot, which can balance requirements for higher oxygen content in the stage of seeding and lower oxygen content in the stage of constant-diameter growth, thereby increasing the quality and production of the single-crystal silicon ingot. In some embodiments, in the stage of silicon melting, the oxygen passing gap is a third distance H₃, and the third distance H₃ is set to 20 mm to 30 mm. In the stage of seeding, the first distance H₁ is adjusted to 32 mm to 45 mm. In this embodiment, during assembly of the single crystal growing furnace 1, the heat insulation cylinder 12 is raised or lowered as a whole by adding a felt to or removing a felt below the heat insulation cylinder 12, and a height of the support ring 122 may change as the heat insulation cylinder 12 is raised or lowered, so as to adjust the third distance H₃. The third distance H₃ is adjusted within a range of 20 mm to 30 mm. In the stage of seeding, the heater 13 is controlled to move in a direction away from the support ring 122, and the first distance H₁ is adjusted within a range of 35 mm to 42 mm to increase the oxygen content in the single crystal growing furnace 1 in the stage of seeding.

In some embodiments, in the stage of seeding, the first distance H₁ may be adjusted to 35 mm to 42 mm. For example, the first distance H₁ may be adjusted to 36 mm, 38 mm, 40 mm, 42 mm, or the like.

In some embodiments, in the stage of seeding, the first distance H₁ may be adjusted to 38 mm to 40 mm. For example, the first distance H₁ may be adjusted to 38 mm, 39 mm, 40 mm, or the like.

Alternatively, in some embodiments, in the stage of silicon melting, the oxygen passing gap is a third distance H₃, and the third distance H₃ is set to 32 mm to 45 mm. In the stage of seeding, the oxygen passing gap H remains unchanged. In this embodiment, during assembly of the single crystal growing furnace 1, the third distance H₃ is directly adjusted within a range of 35 mm to 42 mm by adding a felt to or removing a felt below the heat insulation cylinder 12, which reduces movement of the heater 13 in the stage of seeding and reduces an influence on a growth process of the single-crystal silicon ingot.

In some embodiments, in the stage of silicon melting, the third distance H₃ may be adjusted to 35 mm to 42 mm. For example, the third distance H₃ may be adjusted to 36 mm, 38 mm, 40 mm, 42 mm, or the like.

In some embodiments, in the stage of silicon melting, the third distance H₃ may be adjusted to 38 mm to 40 mm. For example, the third distance H₃ may be adjusted to 38 mm, 39 mm, 40 mm, or the like.

In this embodiment, the oxygen passing gap H in the stage of seeding should not be excessively large or excessively small. If the oxygen passing gap H is excessively large (e.g., greater than 45 mm), a movement length of the heater 13 is relatively large, which may affect a heating effect of the crucible 15. If the oxygen passing gap H is excessively small (e.g., less than 32 mm), the oxygen content in the single crystal growing furnace 1 is lower, and the survival rate is reduced.

In some embodiments, in the stage of constant-diameter growth, the second distance H₂ is 20 mm to 30 mm. In this embodiment, the second distance H₂ in the stage of constant-diameter growth is adjusted within a range of 20 mm to 30 mm, to reduce the oxygen passing gap H in the stage of constant-diameter growth to reduce the oxygen content in the single crystal growing furnace 1 in the stage of constant-diameter growth.

In some embodiments, in the stage of constant-diameter growth, the second distance H₂ may be adjusted to 22 mm to 30 mm. For example, the second distance H₂ may be 24 mm, 26 mm, 28 mm, 30 mm, or the like.

In some embodiments, in the stage of constant-diameter growth, the second distance H₂ may be adjusted to 25 mm to 28 mm. For example, the second distance H₂ may be 25 mm, 26 mm, 27 mm, 28 mm, or the like.

In this embodiment, the oxygen passing gap H in the stage of constant-diameter growth should not be excessively large or excessively small. If the oxygen passing gap H is excessively large (e.g., greater than 30 mm), the oxygen content in the single crystal growing furnace 1 is higher, which affects the quality of the single-crystal silicon ingot. During the operation of the single crystal growing furnace 1, a current passing through the heater 13 (made of graphite) is very large, and the support ring 122 (made of carbon-carbon) is also made of a conductive material. If the oxygen passing gap H is excessively small (e.g., less than 20 mm), the heater 13 and the support ring 122 may form a conductive path in a short period of time, resulting in overcurrent and ignition.

In some embodiments, a ratio of the first distance H₁ to the second distance H₂ may range from 1.1 to 2.1. For example, H₁:H₂ may be 1.2, 1.5, 1.8, 2.1, or the like.

In this embodiment, H₁:H₂ should not be excessively large or excessively small. If the value of H₁:H₂ is excessively small (e.g., less than 1.1), values of H₁ and H₂ are close, causing the oxygen passing gap H in the stage of seeding to be excessively small or the oxygen passing gap H in the stage of constant-diameter growth to be excessively large, which affects production of the single-crystal silicon ingot or reduces the quality of the single-crystal silicon ingot. If the value of H₁:H₂ is excessively large (e.g., greater than 2.1), the value of H₁ may be excessively large or the value of H₂ may be excessively small. During the operation of the single crystal growing furnace 1, the current passing through the heater 13 (made of graphite) is very large, and the support ring 122 (made of carbon-carbon) is also made of a conductive material. If the value of H₂ is excessively small, the heater 13 and the support ring 122 may form a conductive path in a short period of time, resulting in overcurrent and ignition. If the value of H₁ is excessively large, the movement length of the heater 13 is relatively large, which may affect the heating effect of the crucible 15.

Further, to ensure the quality of the single-crystal silicon ingot in the stage of constant-diameter growth, there is a need to adjust the oxygen passing gap H from the first distance to the second distance in the stage of shoulder turning, so that the adjustment of the oxygen passing gap H is completed before the stage of constant-diameter growth or concurrently with the starting of the stage of constant-diameter growth.

For example, in this embodiment, during the manufacturing of the single-crystal silicon ingot, the stage of seeding and the stage of shoulder putting take about 150 min, and the oxygen passing gap H may be gradually adjusted to 32 mm to 40 mm. The stage of shoulder turning takes about 10 min, and the oxygen passing gap H may be gradually adjusted to 28 mm to 32 mm. The stage of constant-diameter growth takes about 40 h to 60 h, and the oxygen passing gap H may be gradually adjusted to 21 mm to 28 mm before the stage of constant-diameter growth or may be adjusted to 21 mm to 28 mm concurrently with the starting of the stage of constant-diameter growth.

The following table shows different oxygen passing gaps H during multiple manufacturing processes of the single-crystal silicon ingot, and oxygen contents at a head of the single-crystal silicon ingot and survival rates. It is to be noted that other parameters of the manufacturing processes of the single-crystal silicon ingot are all the same and are not described in detail one by one herein.

Oxygen passing gaps and corresponding processes

| Oxygen passing gap | Ingot head oxygen content | Survival rate |
|---|---|---|
| (mm) | (ppma) | (%) |
| 20 | 9.22 | 73.13 |
| 25 | 9.87 | 76.23 |
| 30 | 10.56 | 79.45 |
| 35 | 11.31 | 82.36 |
| 40 | 12.65 | 85.83 |

In the above table, the values in the first column represent values of oxygen passing gaps H during 5 manufacturing processes of the single-crystal silicon ingot, the values in the second column represent values of oxygen content at the head of the single-crystal silicon ingot obtained by the 5 manufacturing processes, and the values in the third column represent survival rates corresponding to values of 5 oxygen contents of the 5 manufacturing processes. In the first row, the oxygen passing gap H is 20 mm during the manufacturing of the single-crystal silicon ingot, the oxygen content at the head of the single-crystal silicon ingot is 9.22 ppma, and the survival rate of the single-crystal silicon ingot is 73.13%. In the second row, the oxygen passing gap H is 25 mm during the manufacturing of the single-crystal silicon ingot, the oxygen content at the head of the single-crystal silicon ingot is 9.87 ppma, and the survival rate of the single-crystal silicon ingot is 76.23%. In the third row, the oxygen passing gap H is 30 mm during the manufacturing of the single-crystal silicon ingot, the oxygen content at the head of the single-crystal silicon ingot is 10.56 ppma, and the survival rate of the single-crystal silicon ingot is 79.45%. In the fourth row, the oxygen passing gap H is 35 mm during the manufacturing of the single-crystal silicon ingot, the oxygen content at the head of the single-crystal silicon ingot is 11.31 ppma, and the survival rate of the single-crystal silicon ingot is 82.36%. In the fifth row, the oxygen passing gap H is 40 mm during the manufacturing of the single-crystal silicon ingot, the oxygen content at the head of the single-crystal silicon ingot is 12.65 ppma, and the survival rate of the single-crystal silicon ingot is 85.83%.

As can be seen from the process values in the above table, if the value of the oxygen passing gap is greater, the ingot head oxygen content is higher, and the survival rate is higher. In the current single-crystal silicon ingot, the larger the oxygen content, the better the quality of a single-crystal process. Therefore, during the manufacturing of the single-crystal silicon ingot, in order to increase the ingot head oxygen content, there is a need to enlarge the oxygen passing gap in the stage of seeding and the stage of shoulder putting, and in order to improve the quality of the ingot, there is a need to reduce the oxygen passing gap in the stage of constant-diameter growth.

To this end, in this embodiment, the heater 13 is controlled to move relative to the support ring 122 during the manufacturing of the single-crystal silicon ingot, so as to change the oxygen passing gap H, namely, increase the oxygen passing gap H in the stage of seeding and reduce the oxygen passing gap H in the stage of constant-diameter growth. The requirement for higher oxygen content in the stage of seeding and the requirement for lower oxygen content in the stage of constant-diameter growth are both satisfied, thereby increasing production of the single-crystal silicon ingot and improving the quality of the single-crystal silicon ingot.

The following table shows process values in Comparison Solution 1, Comparison Solution 2, and Comparison Solution 3 in the stage of seeding and the stage of constant-diameter growth, and process values in Solution 1, Solution 2, and Solution 3 of the present disclosure in the stage of seeding and the stage of constant-diameter growth, and a survival rate of a qualified solution is no less than 80%. It is to be noted that other parameters of the manufacturing processes of the single-crystal silicon ingot are all the same and are not described in detail one by one herein.

Comparison table

| | Oxygen passing gap (mm) | | Ingot head | |
|---|---|---|---|---|
| | Stage of | Stage of constant- | oxygen content | Survival |
| | seeding | diameter growth | (ppma) | rate (%) |
| Comparison | 27 | 40 | 9.76 | 76.13 |
| solution 1 | | | | |
| Comparison | 32 | 32 | 11.26 | 79.53 |
| solution 2 | | | | |
| Comparison | 40 | 38 | 12.45 | 85.46 |
| solution 3 | | | | |
| Solution 1 | 38 | 27 | 12.25 | 83.75 |
| Solution 2 | 40 | 25 | 12.85 | 85.45 |
| Solution 3 | 42 | 23 | 13.26 | 86.95 |

As can be seen from the above table, in Comparison Solution 1, the oxygen passing gap H is set to 27 mm in the stage of seeding and is set to 40 mm in the stage of constant-diameter growth, it is obtained that the oxygen content at the head of the single-crystal silicon ingot is 9.76 ppma and the survival rate is 76.13%. For Comparison Solution 1, the lower survival rate in Comparison Solution 1 indicates that there is less oxygen content at the head of the single-crystal silicon ingot when the oxygen passing gap H is set to 27 mm in the stage of seeding. The higher oxygen content in the stage of seeding indicates higher output, and the lower oxygen content in the stage of constant-diameter growth indicates higher quality of the single-crystal silicon ingot. Therefore, in conjunction with Comparison Solution 3 in which a higher survival rate is obtained when the value of the oxygen passing gap H is set to 40 mm in the stage of seeding, when the oxygen passing gap H is set to 40 mm in the stage of seeding in Comparison Solution 1, it may indicate more oxygen content of the single-crystal silicon ingot during constant-diameter growth, which may reduce the quality of the single-crystal silicon ingot.

In Comparison Solution 2, the oxygen passing gap H is set to 32 mm in the stage of seeding and the oxygen passing gap H is set to 32 mm in the stage of constant-diameter growth, the oxygen content at the head of the single-crystal silicon ingot is 10.46 ppma, and the survival rate is 79.53%. For Comparison Solution 2, the lower survival rate in Comparison Solution 2 indicates that there is less oxygen content at the head of the single-crystal silicon ingot when the oxygen passing gap H is set to 32 mm in the stage of seeding. When the oxygen passing gap H in the stage of constant-diameter growth remains unchanged, in conjunction with the value of the oxygen content at the head of the ingot obtained when the oxygen passing gap H in the stage of seeding is set to 32 mm, the oxygen content in the stage of constant-diameter growth is also about 11.26 ppma, which is relatively high and affects the quality of the single-crystal silicon ingot.

In Comparison Solution 3, the oxygen passing gap H is set to 40 mm in the stage of seeding and the oxygen passing gap H is set to 38 mm in the stage of constant-diameter growth, the oxygen content at the head of the single-crystal silicon ingot is 12.45 ppma, and the survival rate is 85.46%. For Comparison Solution 3, the higher survival rate in Comparison Solution 3 indicates that the oxygen content at the head of the single-crystal silicon ingot is more when the oxygen passing gap H is set to 40 mm in the stage of seeding. In Comparison Solution 3, the oxygen passing gap H in the stage of constant-diameter growth is 38 mm, which is close to the oxygen passing gap H in the stage of seeding. This indicates that there is more oxygen content in the stage of constant-diameter growth, resulting in a reduction in the quality of the single-crystal silicon ingot.

In Solution 1, the oxygen passing gap H is set to 38 mm in the stage of seeding and the oxygen passing gap H is set to 27 mm in the stage of constant-diameter growth, the oxygen content at the head of the single-crystal silicon ingot is 12.25 ppma, and the survival rate is 83.75%. For Solution 1, the higher survival rate in Solution 1 indicates that there is more oxygen content at the head of the single-crystal silicon ingot when the oxygen passing gap H is set to 38 mm in the stage of seeding. In conjunction with the value of the oxygen content at the head of the ingot obtained when the oxygen passing gap H in the stage of seeding is 27 mm in Comparison Solution 1, the oxygen content in the stage of constant-diameter growth is about 9.76 ppma in Solution 1, which has less oxygen content and improves the quality of the single-crystal silicon ingot.

In Solution 2, the oxygen passing gap H is set to 40 mm in the stage of seeding and the oxygen passing gap H is set to 25 mm in the stage of constant-diameter growth, the oxygen content at the head of the single-crystal silicon ingot is 12.85 ppma, and the survival rate is 85.45%. For Solution 2, the higher survival rate in Solution 2 indicates that there is more oxygen content at the head of the single-crystal silicon ingot when the oxygen passing gap H is set to 40 mm in the stage of seeding. In conjunction with the value of the oxygen content at the head of the ingot obtained when the oxygen passing gap H in the stage of seeding is 27 mm in Comparison Solution 1, the oxygen content in the stage of constant-diameter growth is below 9.76 ppma in Solution 1, which has less oxygen content and improves the quality of the single-crystal silicon ingot.

In Solution 3, the oxygen passing gap H is set to 42 mm in the stage of seeding and the oxygen passing gap H is set to 23 mm in the stage of constant-diameter growth, the oxygen content at the head of the single-crystal silicon ingot is 13.26 ppma, and the survival rate is 86.95%. For Solution 3, the higher survival rate in Solution 3 indicates that there is more oxygen content at the head of the single-crystal silicon ingot when the oxygen passing gap H is set to 42 mm in the stage of seeding. In conjunction with the value of the oxygen content at the head of the ingot obtained when the oxygen passing gap H in the stage of seeding is 27 mm in Comparison Solution 1, the oxygen content in the stage of diameter equalization is below 9.76 ppma in Solution 1, which has less oxygen content and improves the quality of the single-crystal silicon ingot.

As can be seen from the test results in the above table, the values of the oxygen passing gap H in the stage of seeding in Solution 1, Solution 2, and Solution 3 are within a range (35 mm to 42 mm) defined by the present disclosure, and the survival rates in Solution 1, Solution 2, and Solution 3 are greater than 80%. The values of the oxygen passing gap H in Comparison Solution 1 and Comparison Solution 2 are outside the range defined by the present disclosure, and the survival rates in Comparison Solution 1 and Comparison Solution 2 are less than 80%.

In addition, the higher oxygen content in the stage of seeding results in higher output, and the lower oxygen content in the stage of constant-diameter growth results in higher quality of the single-crystal silicon ingot. In conjunction with the values in the comparison solutions and the solutions of the present disclosure, when the oxygen passing gap H in the stage of constant-diameter growth is smaller, there is lower oxygen content in the generated crystal, and the single-crystal silicon ingot manufactured has better quality. The values of the oxygen passing gap H in the stage of constant-diameter growth in Solution 1, Solution 2, and Solution 3 are within a range (20 mm to 30 mm) limited in the present disclosure, and the values of the oxygen passing gap H in the stage of constant-diameter growth in comparison Solution 2 and comparison Solution 3 are outside the range limited in the present disclosure.

Therefore, during the manufacturing of the single-crystal silicon ingot, when the oxygen passing gap in the stage of seeding is adjusted to 35 mm to 42 mm and the oxygen passing gap in the stage of constant-diameter growth is adjusted to 20 mm to 30 mm, the oxygen content at the head of the single-crystal silicon ingot in the stage of seeding can be increased, and the oxygen content at the head of the single-crystal silicon ingot in the stage of constant-diameter growth can be reduced, thereby increasing the survival rate of the single-crystal silicon ingot and improving the quality.

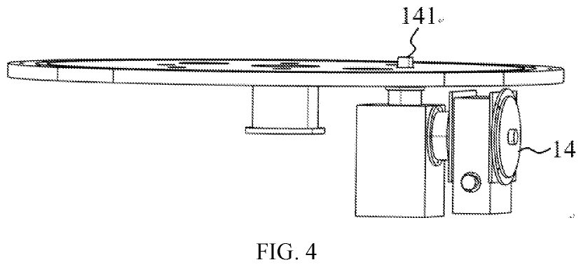

In order to realize the above method, as shown in FIG. 1 and FIG. 4, this disclosure further provides a single crystal growing furnace 1. The single crystal growing furnace 1 includes a furnace body 11, a heat insulation cylinder 12, a crucible 15, a heater 13, and a driving member 14. The heat insulation cylinder 12 is arranged in the furnace body 11. The heat insulation cylinder 12 includes an upper heat insulation cylinder 121, a middle heat insulation cylinder 123, a lower heat insulation cylinder 124, and a support ring 122. The upper heat insulation cylinder 121, the middle heat insulation cylinder 123, and the lower heat insulation cylinder 124 are sequentially arranged along a height direction Z of the single crystal growing furnace 1. Diameters of the lower heat insulation cylinder 124 and the middle heat insulation cylinder 123 are the same. The middle heat insulation cylinder 123 may be directly connected to the lower heat insulation cylinder 124. A diameter of the upper heat insulation cylinder 121 is less than that of the middle heat insulation cylinder 123. The support ring 122 is arranged between the upper heat insulation cylinder 121 and the middle heat insulation cylinder 123 for transitional support, to realize a connection between the upper heat insulation cylinder 121 and the middle heat insulation cylinder 123. The crucible 15 is arranged in the heat insulation cylinder 12. The heater 13 is arranged in the heat insulation cylinder 12 and located on a periphery of the crucible 15. An upper surface of the heater 13 and an upper surface of the crucible 15 are at a same height. The driving member 14 is arranged below a furnace bottom of the furnace body 11.

As shown in FIG. 1. FIG. 2, and FIG. 4, along the height direction Z of the single crystal growing furnace 1, the heater 13 is located below the support ring 122, and a distance between the top of the heater 13 and the bottom of the support ring 122 is an oxygen passing gap H. Part of the driving member 14 can pass through the furnace bottom of the furnace body 11 and be connected to the heater 13. The driving member 14 can drive the heater 13 to move relative to the heat insulation cylinder 12 to adjust the oxygen passing gap H. A size of the oxygen passing gap H is used to control oxygen concentration during crystal growth. If the oxygen passing gap H is larger, a flow rate of oxygen is lower, and less oxygen is discharged outwards, which means that there is more oxygen content during the single crystal growth. If the oxygen passing gap H is smaller, the flow rate of oxygen is higher, and more oxygen is discharged outwards, which means that there is lower oxygen content during the single crystal growth.

In this embodiment, the driving member 14 can drive the heater 13 to move up and down to adjust the distance between the top of the heater 13 and the bottom of the support ring 122, thereby adjusting the oxygen passing gap H. For example, before or during the stage of seeding, the driving member 14 drives the heater 13 to move down to increase the oxygen passing gap H, so that the flow rate of oxygen discharged by the oxygen passing gap H is reduced and the oxygen content in the stage of seeding is increased, thereby increase the seeding survival rate and productivity. Before the stage of constant-diameter growth, the driving member 14 drives the heater 13 to move up to reduce the oxygen passing gap H, so that the flow rate of oxygen discharged along the oxygen passing gap H is increased and the oxygen content in the stage of constant-diameter growth is reduced, thereby improving the quality of the single-crystal silicon ingot.

As shown in FIG. 1. FIG. 3, and FIG. 4, in some embodiments, the heater 13 further includes a heating body 131, a heating plate 132, and an electrode column 133 connected to each other. The heating body 131 is arranged on a periphery of the crucible 15, and a distance between the top of the heating body 131 and the bottom of the support ring 122 is the oxygen passing gap H. An end of the heating plate 132 close to the electrode column 133 is provided with an extension portion 132a extending towards the crucible 15. The extension portion 132a fits the electrode column 133. Part of the driving member 14 can pass through the furnace bottom of the furnace body 11 to fit the electrode column 133.

In this embodiment, the driving member 14 drives the electrode column 133 to move, the electrode column 133 drives the heating plate 132 to move, and the heating plate 132 drives the heating body 131 to move, to adjust the distance between the top of the heating body 131 and the bottom of the support ring 122, thereby adjusting the oxygen passing gap H. The structure of the heater 13 is connected to the driving member 14, so that the electrode column 133 and the heating plate 132 can transfer a current and can also support the heating body 131 and drive the heating body 131 to move, which reduces the arrangement of other transmission mechanisms and saves costs and space.

In this embodiment, at least two electrode columns 133 and at least two heating plates 132 are provided. The two heating plates 132 are evenly arranged on a lower part of the heating body 131, and the two electrode columns 133 are connected correspondingly to the two heating plates 132 to ensure stability of the heater 13 during lifting. A number of the driving member 14 may be set according to an actual situation. For example, one driving member 14 is provided, and the driving member 14 simultaneously drives the two electrode columns 133 to move. Alternatively, the number of the driving member is set to the number of the electrode column 133, and each driving member 14 drives the corresponding electrode column 133.

A fitting position of the driving member 14, the bottom wall of the furnace body 11, and the electrode column 133 is sealed by magnetic fluid. The magnetic fluid is a magnetically permeable material that exists in a form of liquid and can seal vacuum and isolate gas. Since a temperature in the single crystal growing furnace 1 is relatively high, the fitting position of the driving member 14, the bottom wall of the furnace body 11, and the electrode column 133 is sealed by magnetic fluid, so that temperature resistance of the driving member 14 may reach −40° C. to 200° C., ensuring normal operation of the driving member 14.

Further, the driving member includes a first sealing member (not shown). The first sealing member seals the magnetic fluid arranged at the fitting position of the driving member 14, the bottom wall of the furnace body 11, and the electrode column 133. Water is arranged for the first sealing member for real-time cooling, taking away heat generated by the driving member 14 and heat transferred from the single crystal growing furnace 1, which ensures that the magnetic fluid may not dry up and cause air leakage, thereby ensuring a sealing effect of the magnetic fluid.

As shown in FIG. 1 and FIG. 4, in some embodiments, the driving member 14 further includes a driving motor (not shown), a gear (not shown), and a screw 141. A driving shaft of the driving motor is fixed with the gear, the gear is engaged with the screw 141, and the screw 141 is engaged with the electrode column 133. A connecting end of the screw 141 connecting to the electrode column 133 is a copper electrode.

In this embodiment, the gear sleeves the driving shaft of the driving motor, and the screw 141 is meshed with the gear. The driving shaft of the driving motor is controlled to rotate clockwise or counterclockwise, the driving shaft of the driving motor drives the gear to rotate clockwise or counterclockwise, and the gear drives the screw 141 to rise and fall, thereby realizing rising and falling of the electrode column 133 and realizing rising and falling of the heater 13. The end of the screw connecting to the electrode column 133 is the copper electrode, and the copper electrode may be connected to a power supply to transfer a current to the electrode column 133 after the copper electrode is connected to the electrode column 133. It is to be noted that an end of the screw 141 close to the copper electrode is further provided with an insulating material.

A bellows further sleeves the screw 141 to seal and protect the screw 141, which prevents entry of dust. A flange, a bearing, or the like may alternatively be arranged at a fitting position of the driving motor, the gear, and the screw 141, which is not limited herein in this embodiment.

The above descriptions are only some embodiments of the present disclosure and are not intended to limit the present disclosure. For those skilled in the art, the present disclosure may have various modifications and changes. Any modifications, equivalent replacements, improvements, and the like made within the spirit and principles of the present disclosure shall be included in the protection scope of the present disclosure.

What is claimed is:

1. A method for manufacturing a single-crystal silicon ingot in a single crystal growing furnace, wherein the single crystal growing furnace comprises a furnace body, a heat insulation cylinder, a heater, and a crucible, the heat insulation cylinder is arranged in the furnace body, the heater is arranged in the heat insulation cylinder, and the heater is located on a periphery of the crucible,
the heat insulation cylinder comprises an upper heat insulation cylinder, a middle heat insulation cylinder, a lower heat insulation cylinder, and a support ring, the support ring is located between the upper heat insulation cylinder and the middle heat insulation cylinder, along a height direction of the single crystal growing furnace, a distance between a top of the heater and a bottom of the support ring is an oxygen passing gap, and the heater is movable relative to the support ring to adjust the oxygen passing gap,
wherein the method comprises: silicon melting, seeding, shoulder putting, shoulder turning, constant-diameter growth, tailing, and cooling,
wherein the oxygen passing gap is a first distance in the stage of seeding and is a second distance in the stage of constant-diameter growth, where the first distance is greater than the second distance.

2. The method according to claim 1, wherein, in the stage of silicon melting, the oxygen passing gap is a third distance, and the third distance ranges from 20 mm to 30 mm, and
in the stage of seeding, the first distance is adjusted to 35 mm to 42 mm.

3. The method according to claim 1, wherein, in the stage of silicon melting, the oxygen passing gap is a third distance, and the third distance ranges from 35 mm to 42 mm, and
in the stage of seeding, the oxygen passing gap remains unchanged.

4. The method according to claim 1, wherein, in the stage of constant-diameter growth, the second distance ranges from 22 mm to 30 mm.

5. The method according to claim 4, wherein, in the stage of shoulder turning, the oxygen passing gap is adjusted from the first distance to the second distance, so that the adjustment of the oxygen passing gap is completed before the stage of constant-diameter growth or concurrently with entering of the stage of constant-diameter growth.

6. The method according to claim 1, wherein, in the stage of seeding, the first distance ranges from 38 mm to 40 mm.

7. The method according to claim 1, wherein, in the stage of silicon melting, the oxygen passing gap is a third distance, and the third distance ranges from 35 mm to 42 mm.

8. The method according to claim 7, wherein, in the stage of silicon melting, the third distance ranges from 38 mm to 40 mm.

9. The method according to claim 1, wherein, in the stage of constant-diameter growth, the second distance ranges from 25 mm to 28 mm.

10. The method according to claim 1, wherein a ratio of the first distance to the second distance ranges from 1.1:1 to 2.1:1.

11. A single crystal growing furnace, comprising:
a furnace body;
a heat insulation cylinder arranged in the furnace body, wherein the heat insulation cylinder comprises an upper heat insulation cylinder, a middle heat insulation cylinder, a lower heat insulation cylinder, and a support ring, and the support ring is located between the upper heat insulation cylinder and the middle heat insulation cylinder;
a crucible arranged in the heat insulation cylinder;
a heater arranged in the heat insulation cylinder and located on a periphery of the crucible, wherein along a height direction of the single crystal growing furnace, a distance between a top of the heater and a bottom of the support ring is an oxygen passing gap; and
a driving member connected to the heater, wherein the driving member is configured to drive the heater to move relative to the heat insulation cylinder to adjust the oxygen passing gap.

12. The single crystal growing furnace according to claim 11, wherein the heater comprises a heating body, a heating plate, and an electrode column connected to each other,
the heating body is arranged on the periphery of the crucible, and a distance between a top of the heating body and the bottom of the support ring is the oxygen passing gap, and
an end of the heating plate close to the electrode column is provided with an extension portion extending towards the crucible, and the extension portion fits the electrode column.

13. The single crystal growing furnace according to claim 12, wherein a part of the driving member passes through a bottom wall of the furnace body to fit the electrode column, and
a fitting position of the driving member, the bottom wall of the furnace body, and the electrode column is sealed by magnetic fluid.

14. The single crystal growing furnace according to claim 13, wherein the driving member comprises a first sealing member, and
the first sealing member seals the magnetic fluid at the fitting position of the driving member, the bottom wall of the furnace body, and the electrode column.

15. The single crystal growing furnace according to claim 12, wherein the driving member further comprises a driving motor, a gear, and a screw,
a driving shaft of the driving motor is fixed with the gear, the gear is engaged with the screw, and the screw fits the electrode column, and
a connecting end of the screw connecting to the electrode column is a copper electrode.

16. The single crystal growing furnace according to claim 11, wherein the heater is made of graphite.

17. The single crystal growing furnace according to claim 11, wherein the heater surrounds the crucible.

18. The single crystal growing furnace according to claim 11, wherein the support ring comprises an inner part in contact with the upper heat insulation cylinder, and an outer part in contact with the middle heat insulation cylinder.

19. The single crystal growing furnace according to claim 18, wherein the support ring further comprises a middle part, and a thickness of the middle part is greater than a thickness of the inner part and is also greater than a thickness of the outer part.

20. The single crystal growing furnace according to claim 11, wherein the heater is arranged in the middle heat insulation cylinder.
